(19) United States
(12) Patent Application Publication
(10) Pub. No.: US 2026/0034897 A1
(43) Pub. Date: Feb. 5, 2026

(54) ACTIVATION APPARATUS AND METHOD

(71) Applicant: Honda Motor Co., Ltd., Tokyo (JP)

(72) Inventors: Masato Otake, Saitama (JP); Yusuke Shindo, Saitama (JP)

(21) Appl. No.: 19/281,627

(22) Filed: Jul. 26, 2025

(30) Foreign Application Priority Data
Aug. 1, 2024 (JP) 2024-126063

(51) Int. Cl. B60L 50/60; G01R 19/00

(52) U.S. Cl. CPC B60L 50/60; G01R 19/0084; B60L 2260/44

(57) ABSTRACT

An activation apparatus for a second system, which activates by receiving power from a first system including a battery, a load, and a precharge circuit. The systems are connected such that the second system and the load are in parallel. The apparatus includes a voltage sensor and a microprocessor. The microprocessor instructs an activation attempt when a voltage measured during precharge satisfies a first condition, and estimates precharge completion when a voltage measured after the attempt satisfies a second condition.

### CROSS-REFERENCE TO RELATED APPLICATION

This application is based upon and claims the benefit of priority from Japanese Patent Application No. 2024-126063 filed on Aug. 1, 2024, the content of which is incorporated herein by reference.

### BACKGROUND

### Technical Field

The present invention relates to an activation apparatus and an activation method for a second system, which activates by receiving power supply from a first system different from the second system.

### Related Art

As this type of technology, a power control device mounted in an electric vehicle is known (for example, refer to JP 2004-120866 A). In this power control device, when a change rate of a precharge voltage of a battery system falls below a predetermined value, the completion of the precharge is detected.

However, in a case where an electric vehicle is equipped with an independent system (referred to as a second system) separate from the battery system (referred to as a first system), it becomes necessary for the second system to accurately determine the completion of the precharge of the first system. More specifically, in a case where the second system incorrectly determines the completion of the precharge of the first system, activation of the second system may be attempted before the completion of the precharge. In such a case, since power supply from the first system is insufficient before the completion of the precharge, it is assumed that it is difficult to activate the second system.

That is, in the technology in the related art, since the combination with the above second system is not assumed, the technology in the related art cannot be applied, as it is, to a fuel cell vehicle or the like in which the second system such as a fuel cell system is combined with the first system, for example. In other words, in the technology in the related art, it is not possible to accurately determine the completion of the precharge without using communication between the second system and the first system.

Note that the fuel cell system as an example of the second system is considered one effective approach for reducing negative impacts on the global environment, and therefore, the above issue is extremely important.

### SUMMARY

An aspect of the present invention is an activation apparatus for a second system, which activates by receiving power supply from a first system different from the second system, the first system including a battery, a load that receives power supply from the battery, and a precharge circuit provided on a first power line connecting the battery and the load. The first system and the second system are connected via a second power line such that the second system and the load are in parallel. The activation apparatus includes: a voltage sensor configured to measure a voltage of the precharge circuit of the first system via the first power line and the second power line; and a microprocessor. The microprocessor is configured to perform: instructing an activation attempt of the second system when a voltage measured by the voltage sensor during execution of the precharge by the precharge circuit satisfies a first predetermined condition; and estimating completion of the precharge when a voltage measured by the voltage sensor after the activation attempt satisfies a second predetermined condition.

Another aspect of the present invention is an activation method for a second system, which activates by receiving power supply from a first system different from the second system, the first system including a battery, a load that receives power supply from the battery, and a precharge circuit provided on a first power line connecting the battery and the load. The first system and the second system are connected via a second power line such that the second system and the load are in parallel. The activation method includes: a step in which an activation apparatus obtains a detection signal from a voltage sensor configured to measure a voltage of the precharge circuit of the first system via the first power line and the second power line, during execution of the precharge by the precharge circuit; a step in which the activation apparatus instructs an activation attempt of the second system when the voltage based on the detection signal obtained from the sensor satisfies a first predetermined condition; and a step in which the activation apparatus estimates completion of the precharge when the voltage based on the detection signal obtained from the sensor after the activation attempt satisfies a second predetermined condition.

### BRIEF DESCRIPTION OF DRAWINGS

The objects, features, and advantages of the present invention will become clearer from the following description of embodiments in relation to the attached drawings, in which:

FIG. 1 is a schematic configuration diagram illustrating an example of an overall system;

FIG. 2A is a schematic diagram for describing a precharge circuit in the BATT and load system;

FIG. 2B is a schematic diagram for describing a precharge circuit in the BATT and load system;

FIG. 2C is a schematic diagram for describing a precharge circuit in the BATT and load system;

FIG. 3A is a schematic diagram illustrating a change in voltage V2 during a precharge operation;

FIG. 3B is a schematic diagram illustrating a change in voltage V2 during a precharge operation;

FIG. 4 is a flowchart illustrating an example of an activation process executed by a FCMGECU.

### DETAILED DESCRIPTION OF THE INVENTION

### Overview

An overall system equipped with a first system and a second system according to an embodiment of the present invention drives a traction motor serving as a load, using at least one of power (referred to as FC power) generated and output by a fuel cell (hereinafter, sometimes referred to as FC) of the second system and power (referred to as battery power) stored in a secondary battery of the first system. In addition, power (referred to as regenerative power) generated by the traction motor during regeneration is stored in the secondary battery of the first system.

The overall system normally drives the load using both the FC power from the second system and the battery power of the first system by performing charge/discharge control of the secondary battery of the first system, and thereby suppresses consumption of hydrogen as fuel. In addition, in a state where power generation by the fuel cell is not possible, such as before the activation of the second system, the overall system drives the load using only the battery power by performing discharge control of the secondary battery of the first system. Details of such an overall system will be described with reference to the drawings.

### Overall System

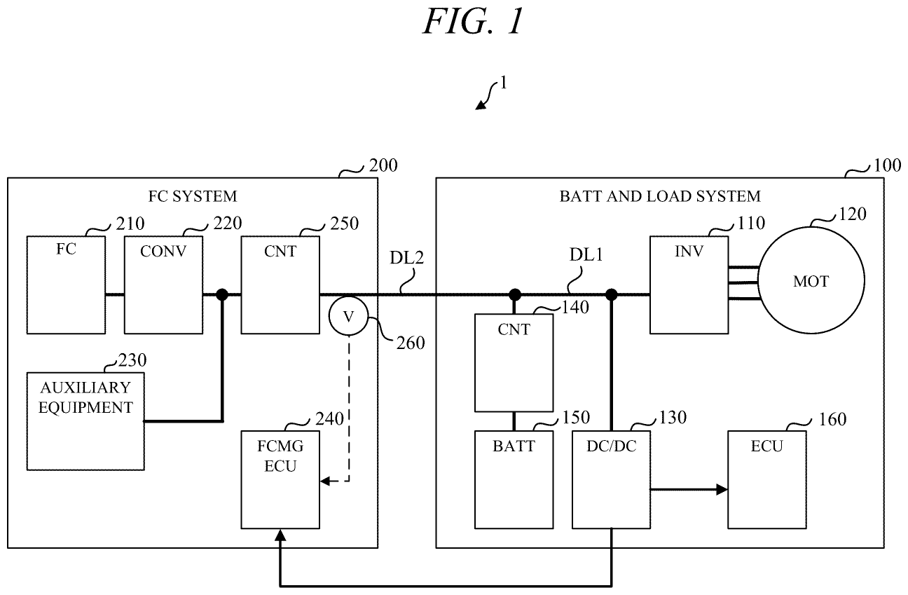

FIG. 1 is a schematic configuration diagram illustrating an example of an overall system 1 according to an embodiment of the invention. As an example, the first system is applied to an electrically powered vehicle driven by a motor 120. In the embodiment, the first system includes a battery (hereinafter sometimes referred to as BATT) and load system 100. In addition, in the embodiment, the second system includes an FC system 200.

The BATT and load system 100 includes at least the traction motor 120, an inverter (INV) 110, a BATT system (power storage device) 150, a DC/DC converter 130, a contactor (CNT) unit 140, and an Electronic Control Unit (ECU) 160.

The FC system 200 includes at least an FC stack 210, a voltage control unit (hereinafter, referred to as a converter (CONV)) 220, auxiliary equipment 230, an FCMGECU (FC Management ECU) 240, a contactor (CNT) unit 250, and a voltage sensor 260. The FCMGECU 240 and the voltage sensor 260 also function as an activation apparatus for the FC system 200.

The BATT and load system 100 and the FC system 200 are connected via a direct-current link DL2. In the embodiment, among the pair of power lines of the positive and negative electrodes for supplying battery power from the BATT system 150 included in the BATT and load system 100, the power lines located outside the BATT and load system 100 are referred to as the direct-current link DL2, and the power lines located inside the BATT and load system 100 are referred to as direct-current link DL1.

The FC system 200 is connected to the BATT system 150 in parallel with the inverter 110, which serves as a load.

Note that the DC voltage supplied from the FC system 200 to the BATT and load system 100 via the direct-current link DL2 is referred to as an FC system voltage. In addition, the DC voltage supplied from the BATT system 150 to the inverter 110 and the FC system 200 via the direct-current links DL1 and DL2 is referred to as a battery voltage.

### BATT and Load System

A configuration of the BATT and load system 100 will be briefly described.

### (Inverter)

The inverter 110 is, for example, a bidirectional DC voltage/AC voltage converter. A direct-current-side terminal of the inverter 110 is connected to the direct-current link DL1. An alternating-current-side terminal of the inverter 110 is connected to the motor 120. In the BATT and load system 100, the contactor unit 140 and the DC/DC converter 130 are connected to the direct-current link DL1.

The inverter 110 converts the DC voltage into a three-phase AC voltage and supplies the three-phase AC voltage to the motor 120. In addition, the inverter 110 converts the AC voltage generated by the regenerative operation of the motor 120 into the DC voltage and outputs the DC voltage to the direct-current link DL1. The voltage obtained by the regenerative operation is referred to as a regenerative voltage.

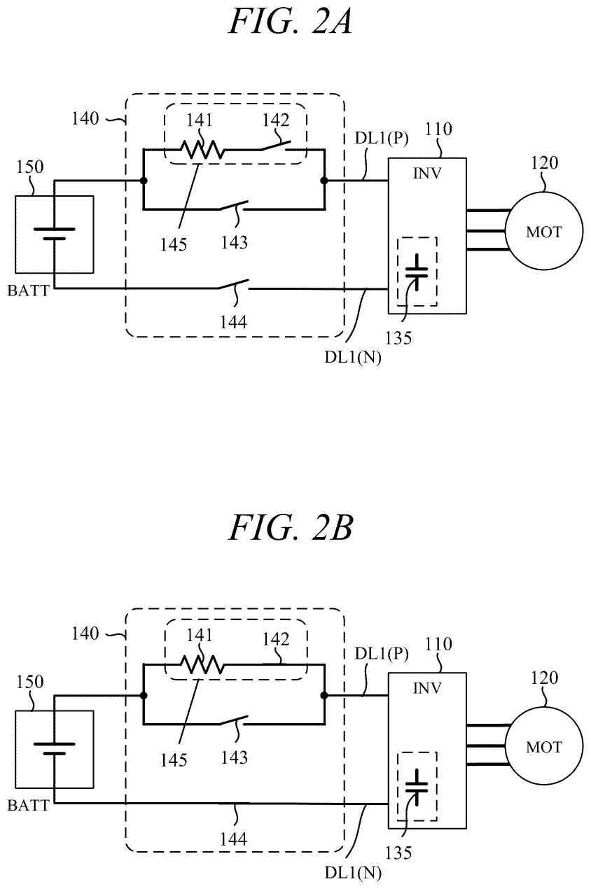

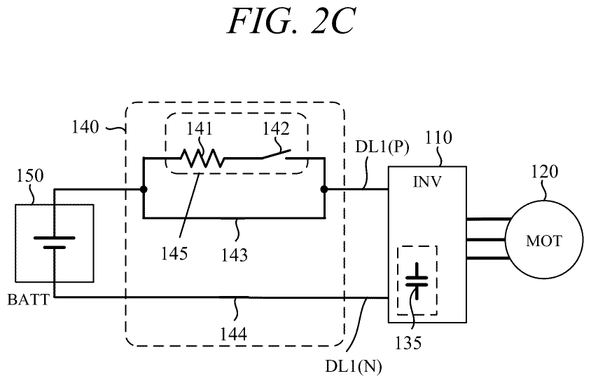

Note that a capacitor 135 (FIGS. 2A to 2C) is provided inside the inverter 110 so as to be connected between the power lines of the positive and negative electrodes.

### (Motor)

The motor 120 is, for example, a three-phase AC electric motor. The rotor of the motor 120 is connected to drive wheels (not illustrated). The motor 120 outputs driving force to the drive wheels using at least one of the FC power supplied from the FC system 200 and the battery power stored in the BATT system 150 (power running operation). In addition, the motor 120 generates power using the kinetic energy of the electrically powered vehicle during deceleration of the electrically powered vehicle (regenerative operation).

### (DC/DC Converter)

The DC/DC converter 130 is configured, for example, by a step-down DC voltage converter, and converts the FC system voltage, battery voltage, and regenerative voltage of several hundred volts DC, into a voltage (for example, 12 V DC or 24 V DC) required by auxiliary equipment including the ECU 160. The auxiliary equipment to which the DC/DC converter 130 supplies power includes an electrical component that does not directly affect power generation or traveling. The power from the DC/DC converter 130 is also supplied to the FCMGECU 240 of the FC system 200.

Note that, in order to enable power supply to the ECU 160 and the like even before the DC/DC converter 130 starts operating, an auxiliary battery (for example, 12 V DC or 24 V DC) (not illustrated) may be provided alongside the DC/DC converter 130. In this case, the auxiliary battery is charged when the DC/DC converter 130 starts operating.

### (Contactor Unit)

The contactor unit 140 connects or disconnects the BATT system 150 to and from the direct-current link DL1.

FIG. 2A is a schematic diagram for describing a precharge circuit in the BATT and load system 100. An internal configuration of the contactor unit 140 will be described with reference to FIG. 2A. In FIG. 2A, a switch (hereinafter, referred to as a main contactor) 143 including an electromagnetic contactor is provided on the direct-current link DL1 connected to the positive electrode of the secondary battery of the BATT system 150. In addition, a switch (hereinafter, referred to as a main contactor) 144 including an electromagnetic contactor is provided on the direct-current link DL1 connected to the negative electrode of the secondary battery of the BATT system 150. Here, the positive electrode side of the direct-current link DL1 is denoted by DL1 (P), and the negative electrode side is denoted by DL1(N).

Furthermore, a precharge circuit 145 is provided in parallel with the main contactor 143. The precharge circuit 145 includes a resistor 141 and a switch (hereinafter, referred to as a precharge contactor) 142 including an electromagnetic contactor.

An instruction for connection and disconnection of the main contactors 143 and 144 and the precharge contactor 142 of the contactor unit 140 is sent, as an example, from the ECU 160.

In the embodiment, the side of the contactor unit 140 close to the BATT system 150 may be referred to as a primary side, and the side of the contactor unit 140 close to the inverter 110 may be referred to as a secondary side.

The battery power output from the BATT system 150 is output to the direct-current link DL1 via the contactor unit 140 in a state where the main contactors 143 and 144 are connected. The regenerative power output from the inverter 110 is output to the BATT system 150 via the contactor unit 140 in a state where the main contactors 143 and 144 are connected.

### (Battery System)

As an example, the BATT system 150 stores (charges) regenerative power obtained through the regenerative operation of the motor 120 or FC power obtained through a power generation operation of the FC system 200 in the secondary battery, and performs discharging from the secondary battery to drive the electrically powered vehicle and operate the auxiliary equipment group. The BATT system 150 includes, as an example, a lithium-ion battery or the like as the secondary battery.

The BATT system 150 detects a current value, a voltage value, and a temperature of the secondary battery using a sensor group (not illustrated), and calculates the State Of Charge (SOC, also referred to as a battery charge rate) of the secondary battery. A signal indicating the calculated SOC is output to the ECU 160.

The ECU 160 controls each unit of the BATT and load system 100. In addition, the ECU 160 determines the required load on the basis of, for example, inputs (load requests) from various switches and sensors (not illustrated) in addition to the state of the BATT system 150 and the state of the motor 120. Then, the distribution (sharing) of the load to be borne by the BATT system 150 and the load to be borne by the motor 120 as a regenerative power source is determined while being adjusted, and an instruction is sent to the motor 120, the inverter 110, the BATT system 150, and the like.

### FC System

A configuration of the FC system 200 will be briefly described.

### (FC Stack)

The FC stack 210 generates power by causing a reaction between hydrogen contained as a fuel in a fuel gas, and oxygen contained as an oxidizing agent in air. In the embodiment, the FC power generated by the FC stack 210 and boosted by the converter 220 is output to the above-described direct-current link DL2 via the contactor unit 250. As a result, the FC power output from the FC system 200 is supplied to the motor 120 via the inverter 110, or to the BATT system 150 via the contactor unit 140.

### (Converter)

The converter 220 includes a step-up DC voltage converter. As an example, the converter 220 controls the FC current output from the FC system 200 while boosting the generated voltage PGV output from the FC stack 210 to a target voltage (referred to as TV). For example, by setting the target voltage TV that is higher than the voltage output from the FC system 200 (referred to as PTV), the FC current may be changed according to the voltage difference between the target voltage TV and the voltage PTV.

The FCMGECU 240 may estimate the remaining capacity of the secondary battery of the BATT system 150, for example, using the voltage supplied from the BATT and load system 100, and the target voltage TV may be determined on the basis of the estimated value.

### (Auxiliary Equipment)

The auxiliary equipment 230 is, for example, an air pump or the like that is driven and controlled by the FCMGECU 240. The FC system 200 compresses air taken in from the outside by the air pump. The compressed air is used for power generation in the FC stack 210.

A heater for warming gas or the FC stack 210 in a cold region or the like may also be added as the auxiliary equipment 230.

As the power consumed by the auxiliary equipment 230, the battery power from the BATT and load system 100 is supplied via the direct-current link DL2 in a state where the contactor unit 250 to be described later is connected. This supply is also possible before the activation of the FC system 200 (in other words, before the start of the power generation). Once the FC system 200 starts operating (in other words, during power generation), FC power can be supplied to the auxiliary equipment 230.

Note that the auxiliary equipment 230 is different from the auxiliary equipment operating on the above-mentioned 12 V DC or 24 V DC.

### (FCMGECU)

The FCMGECU 240 controls each unit of the FC system 200. As an example, during the operation of the FC system 200 (in other words, during power generation), the FCMGECU 240 controls power generation by the FC stack 210, voltage boosting by the converter 220, operation of the auxiliary equipment 230, connection by the contactor unit 250, and the like, on the basis of the estimated remaining capacity of the secondary battery of the BATT system 150 as described above.

In the embodiment, since the FCMGECU 240 does not communicate with the BATT and load system 100, completion of the precharge operation in the BATT and load system 100 is not notified from the BATT and load system 100. Therefore, when the FC system 200 is activated by the FCMGECU 240 as the activation apparatus, the FCMGECU 240 estimates the completion of the precharge operation in the BATT and load system 100, and then activates the FC system 200. That is, during the execution of the precharge in the BATT and load system 100, when the voltage measured by the voltage sensor 260 to be described later satisfies a first predetermined condition, an activation attempt of the FC system 200 is instructed, and when the voltage measured by the voltage sensor 260 after the activation attempt satisfies a second predetermined condition, it is determined that the precharge of the BATT and load system 100 is completed, and activation of the FC system 200 is permitted. The activation attempt means that the battery power from the BATT and load system 100 is consumed in the FC system 200 before the activation of the FC system 200.

Note that the FCMGECU 240 is not limited to an aspect including only one control unit, and may be an aspect including a plurality of control units such as a control unit for controlling power generation of the FC stack 210, for activating the FC system 200, or for the converter 220.

### (Contactor Unit)

The contactor unit 250 is provided on an output side of the converter 220. That is, although not illustrated, a contactor including an electromagnetic contactor is provided on each of the power line of the positive electrode of the direct-current link DL2 and the power line of the negative electrode of the direct-current link DL2.

As an example, the instruction for connection and disconnection of the contactor unit 250 is sent from the FCMGECU 240. The FC power is supplied to the BATT and load system 100 via the direct-current link DL2 in a state where the contactor unit 250 is connected.

### (Voltage Sensor)

The voltage sensor 260 measures the voltage between the power line of the positive electrode and the power line of the negative electrode of the direct-current link DL2.

The voltage measured by the voltage sensor 260 in a state where the FC system 200 is operating (in other words, during power generation) corresponds to the FC system voltage output from the FC system 200. In addition, the voltage measured by the voltage sensor 260 in a state where the contactor unit 250 is disconnected before the activation of the FC system 200 (in other words, before the start of the power generation) corresponds to the voltage of the direct-current-side terminal of the inverter 110 in the BATT and load system 100. Therefore, the voltage measured by the voltage sensor 260 while the precharge operation is being executed in the BATT and load system 100 substantially corresponds to the voltage (referred to as V2) of the capacitor 135 provided inside the inverter 110.

In the embodiment, the FCMGECU 240 as the activation apparatus for the FC system 200 estimates (may be referred to as determination) the completion of the precharge of the BATT and load system 100 before the activation of the FC system 200 (in other words, before the start of the power generation). When the completion of the precharge is estimated, the FCMGECU 240 permits the activation of the FC system 200.

### Precharge

First, the precharge operation of the BATT and load system 100 will be described. FIGS. 2A, 2B, and 2C are schematic diagrams for describing the precharge circuit in the BATT and load system 100.

As illustrated in FIG. 2A, when the operation of the electrically powered vehicle is stopped (an ignition switch (not illustrated) (may be referred to as a power switch) is off), the main contactor (positive electrode side) 143, the main contactor (negative electrode side) 144, and the precharge contactor 142 of the precharge circuit 145 in the contactor unit 140 are disconnected (turned off).

At this time, power generation by the FC stack 210 in the FC system 200 is stopped, and the contactor on the power line of the positive electrode and the contactor on the power line of the negative electrode of the contactor unit 250 are disconnected (turned off).

When an ignition switch (not illustrated) of the electrically powered vehicle is turned on by the driver, the ECU 160 of the BATT and load system 100, as illustrated in FIG. 2B, connects (turns on) the main contactor (negative electrode side) 144 of the contactor unit 140 and connects (turns on) the precharge contactor 142 of the precharge circuit 145 to start charging the capacitor 135.

At this time, an inrush current flowing through the precharge circuit 145 is limited by the resistor 141 provided in the precharge circuit 145. Then, when the capacitor 135 is charged, the ECU 160, as illustrated in FIG. 2C, connects (turns on) the main contactor (positive electrode side) 143 and disconnects (turns off) the precharge contactor 142.

### Estimation of Completion of Precharge

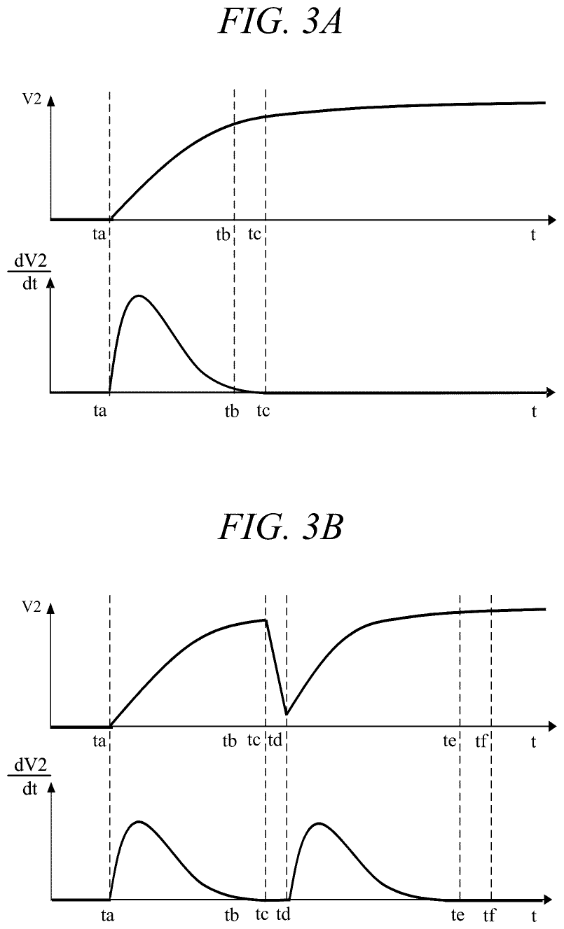

Next, the estimation of the completion of the precharge from the FC system 200 will be described. FIGS. 3A and 3B are schematic diagrams illustrating changes in the voltage V2 of the capacitor 135 during the precharge operation. The curves in the upper graphs of FIGS. 3A and 3B respectively indicate the changes in voltage V2 over time. The curves in the lower graphs of FIGS. 3A and 3B respectively indicate the time derivative (dV2/dt) of the voltage V2 over time.

Note that it is assumed that in FIG. 3A (first example), the SOC of the secondary battery of the BATT system 150 is higher than in FIG. 3B (second example), and therefore the time from the start to the completion of the precharge operation is shorter.

### First Example

In FIG. 3A, a period up to time ta corresponds to an operation stop state (when the ignition switch (not illustrated) is off) of the electrically powered vehicle (FIG. 2A).

When the ignition switch (not illustrated) is turned on by the driver, at time ta, the ECU 160 connects (turns on) the main contactor (negative electrode side) 144 and the precharge contactor 142 of the contactor unit 140 (FIG. 2B). As a result, charging of the capacitor 135 is started, and the voltage V2 starts to rise. In addition, the time derivative (dV2/dt) of the voltage V2 is increased after the start of charging, and then is decreased.

At time tb in FIG. 3A, when the capacitor 135 is substantially charged, the ECU 160 connects (turns on) the main contactor (positive electrode side) 143 and disconnects (turns off) the precharge contactor 142 (FIG. 2C). That is, FIG. 3A illustrates an example in which the precharge is completed at time tb.

On the other hand, on the FC system 200 side, since the states of the main contactor (positive electrode side) 143 and the precharge contactor 142 in the BATT and load system 100 are unknown, it is not known whether or not the precharge is in the completed state.

In order to obtain information for estimating the completion of precharge, the FCMGECU 240 performs an activation attempt at time tc in FIG. 3A, at which a predetermined first condition is satisfied on the basis of the voltage (corresponding to voltage V2) measured by the voltage sensor 260. The activation attempt includes, for example, connecting the contactors (250) of the positive electrode and the negative electrode of the contactor unit 250 of the FC system 200. By connecting the contactors (250) of the contactor unit 250, battery power from the BATT and load system 100 is supplied to the auxiliary equipment 230 via the direct-current link DL2. As a result, an air pump or the like as the auxiliary equipment 230 is driven, and a certain amount of power is consumed by the FC system 200.

In a case where time tc is later than time tb, in other words, in a case where the connection of the contactors (250) of the contactor unit 250 occurs after completion of the precharge, the voltage measured by the voltage sensor 260 does not drop below a predetermined threshold value due to the connection of the contactors (250). The FCMGECU 240 estimates the completion of the precharge on the basis of this phenomenon.

### Second Example

In FIG. 3B, a period up to time ta corresponds to an operation stop state (when the ignition switch (not illustrated) is off) of the electrically powered vehicle (FIG. 2A).

When the ignition switch (not illustrated) of the electrically powered vehicle is turned on by the driver, at time ta, the ECU 160 connects (turns on) the main contactor (negative electrode side) 144 and the precharge contactor 142 of the contactor unit 140 (FIG. 2B). As a result, charging of the capacitor 135 is started, and the voltage V2 starts to rise. In addition, the time derivative (dV2/dt) of the voltage V2 is increased after time elapses from the start of charging, and then is decreased.

At time tb in FIG. 3B, since the charging amount of the capacitor 135 is not sufficient, the ECU 160 maintains the state in which the main contactor (negative electrode side) 144 and the precharge contactor 142 of the contactor unit 140 are connected (turned on) (FIG. 2B). That is, FIG. 3B illustrates an example in which the precharge is not completed at time tb.

On the other hand, on the FC system 200 side, since the states of the main contactor (positive electrode side) 143 and the precharge contactor 142 in the BATT and load system 100 are unknown, it is not known whether or not the precharge is in the completed state.

In order to obtain information for estimating the completion of precharge, the FCMGECU 240 performs an activation attempt at time tc in FIG. 3B, at which a predetermined first condition is satisfied on the basis of the voltage (corresponding to voltage V2) measured by the voltage sensor 260. The activation attempt is similar to the case of FIG. 3A. By connecting the contactors (250) of the contactor unit 250, battery power from the BATT and load system 100 is supplied to the auxiliary equipment 230 via the direct-current link DL2. As a result, an air pump or the like as the auxiliary equipment 230 is driven, and a certain amount of power is consumed by the FC system 200.

In a case where the state of FIG. 2B is maintained at time tc, in other words, in a case where the connection of the contactors (250) of the contactor unit 250 occurs before completion of the precharge, the voltage measured by the voltage sensor 260 drops below a predetermined threshold value due to the connection of the contactors (250). Strictly speaking, connection of the contactors (250)→power supply to the auxiliary equipment 230→occurrence of voltage drop in the resistor 141→drop of voltage measured by the voltage sensor 260→drop of voltage measured by the voltage sensor 260 below a predetermined threshold value. The FCMGECU 240 does not estimate the completion of the precharge on the basis of this phenomenon.

At time td, the FCMGECU 240 causes the contactors (250) of the positive electrode and the negative electrode of the contactor unit 250 of the FC system 200 to be disconnected. As a result of the disconnection of the contactors (250) of the contactor unit 250, the supply of battery power to the auxiliary equipment 230 is stopped. As a result, the charging current to the capacitor 135 is increased, and the voltage V2 starts to rise. In addition, the time derivative (dV2/dt) of the voltage V2 is increased after the resumption of charging, and then is decreased.

At time te in FIG. 3B, when the capacitor 135 is substantially charged, the ECU 160 connects (turns on) the main contactor (positive electrode side) 143 and disconnects (turns off) the precharge contactor 142 (FIG. 2C). That is, FIG. 3B illustrates an example in which the precharge is completed at time te.

On the other hand, on the FC system 200 side, since the states of the main contactor (positive electrode side) 143 and the precharge contactor 142 in the BATT and load system 100 are unknown, it is not known whether or not the precharge is in the completed state.

In order to obtain information for estimating the completion of precharge, the FCMGECU 240 performs an activation retry at time tf in FIG. 3B, at which a predetermined second condition is satisfied on the basis of the voltage (corresponding to voltage V2) measured by the voltage sensor 260. Similarly to the activation attempt, the activation retry includes, for example, connecting the contactors (250) of the positive electrode and the negative electrode of the contactor unit 250 of the FC system 200. By connecting the contactors (250) of the contactor unit 250, battery power from the BATT and load system 100 is supplied to the auxiliary equipment 230 via the direct-current link DL2. As a result, an air pump or the like as the auxiliary equipment 230 is driven, and a certain amount of power is consumed by the FC system 200.

In a case where time tf is later than time te, in other words, in a case where the connection of the contactors (250) of the contactor unit 250 occurs after completion of the precharge, the voltage measured by the voltage sensor 260 does not drop below a predetermined threshold value due to the connection of the contactors (250). The FCMGECU 240 estimates the completion of the precharge on the basis of this phenomenon.

When the completion of the precharge is estimated, the FCMGECU 240 permits the activation of the FC system 200. The FCMGECU 240 uses the battery power supplied from the BATT and load system 100 to open a shut-off valve of a hydrogen tank (not illustrated), for example, and drive the auxiliary equipment 230, and supplies hydrogen and air to the FC stack 210. As a result, power generation by the FC stack 210 is started, and the FC system 200 is operated.

### Description of Flowchart

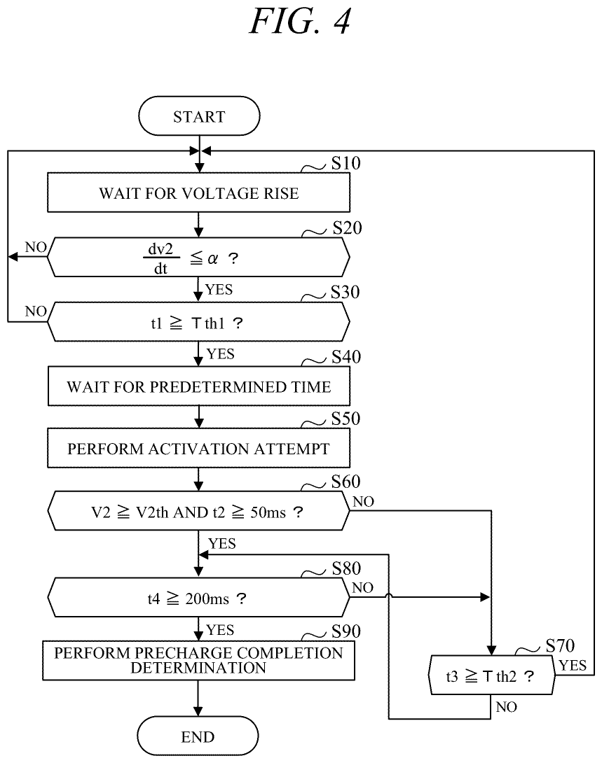

An example of activation processing executed by the FCMGECU 240 as the activation apparatus will be described with reference to the flowchart of FIG. 4. As an example, the FCMGECU 240 starts the processing in FIG. 4 when the ignition switch of the electrically powered vehicle is turned on.

When the voltage measured by the voltage sensor 260 (corresponding to the voltage V2 of the capacitor 135) starts to rise, the FCMGECU 240 starts waiting for the voltage rise in step S10, and the processing proceeds to step S20.

In step S20, the FCMGECU 240 determines whether or not the time derivative (dV2/dt) of the voltage V2 is equal to or less than a predetermined value a. When the value converges to equal to or less than the predetermined value a, the FCMGECU 240 makes an affirmative determination in step S20, and the processing proceeds to step S30. When the value does not converge to equal to or less than the predetermined value a, the FCMGECU 240 makes a negative determination in step S20, and the processing returns to step S10. In a case where the processing returns to step S10, the processing waits until the time derivative (dV2/dt) of the voltage V2 converges to equal to or less than the predetermined value a.

In step S30, the FCMGECU 240 determines whether or not t1≥Tth1 is satisfied. Here, t1 represents a duration during which dV2/dt≤α is satisfied. Tth1 is, for example, 100 msec.

In a case where t1≥Tth1 is satisfied, the FCMGECU 240 makes an affirmative determination in step S30, and the processing proceeds to step S40. In a case where t1≥Tth1 is not satisfied, the FCMGECU 240 makes a negative determination in step S30, and the processing returns to step S10.

In a case where the processing returns to step S10, the above-described processing is repeated.

In step S40, the FCMGECU 240 waits for a predetermined time (for example, the number of activation attempts×50 msec), and the processing proceeds to step S50. The number of activation attempts includes the number of activation retries, which will be described later.

In step S50, the FCMGECU 240 performs an activation attempt, and the processing proceeds to step S60. As described above, the activation attempt includes connecting the contactors (250) of the positive electrode and the negative electrode of the contactor unit 250 of the FC system 200.

In step S60, the FCMGECU 240 determines whether or not V2≥V2th and t2≥50 msec are satisfied. In a case where the above condition is satisfied, the FCMGECU 240 makes an affirmative determination in step S60, and the processing proceeds to step S80. In a case where the condition is not satisfied, the FCMGECU 240 makes a negative determination in step S60, and the processing proceeds to step S70. V2th is a predetermined determination threshold value (as an example, a voltage when the SOC of the secondary battery is 10%). t2 is an elapsed time from the activation attempt (S50).

In step S70, the FCMGECU 240 determines whether or not t3≥Tth2 is satisfied. t3 is a duration of a state in which the voltage V2 is lower than V2th. Tth2 is, for example, 200 msec. In a case where t3≥Tth2 is satisfied, the FCMGECU 240 makes an affirmative determination in step S70, and the processing returns to step S10. In a case where t3≥Tth2 is not satisfied, the FCMGECU 240 makes a negative determination in step S70, and the processing proceeds to step S80.

In step S80, the FCMGECU 240 determines whether or not t4≥200 msec is satisfied. t4 is an elapsed time from the activation attempt (S50). In a case where the above condition is satisfied, the FCMGECU 240 makes an affirmative determination in step S80, and the processing proceeds to step S90. In a case where the condition is not satisfied, the FCMGECU 240 makes a negative determination in step S80, and the processing proceeds to step S70.

In step S90, the FCMGECU 240 performs a precharge completion determination and ends the processing in FIG. 4. In the embodiment, the estimation of the completion of the precharge by the FCMGECU 240 is referred to as “precharge completion determination” by the FCMGECU 240.

According to the above-described embodiments heretofore, the following operation and effects are obtained.

(1) An activation apparatus (240, 260) according to the embodiment is an activation apparatus of the FC system 200 as a second system which activates by receiving power supply from the BATT and load system 100 as a first system including the BATT system 150 as a battery; the inverter 110 as a load that receives power supply from the BATT system 150; and the precharge circuit 145 provided on the direct-current link DL1 as a first power line connecting the BATT system 150 and the inverter 110.

The BATT and load system 100 and the FC system 200 are connected via the direct-current link DL2 as a second power line such that the FC system 200 and the inverter 110 are in parallel. The activation apparatus (240, 260) includes the voltage sensor 260 that measures a voltage of the precharge circuit 145 via the direct-current link DL1 and the direct-current link DL2; and the FCMGECU 240 as a control unit that instructs an activation attempt of the FC system 200 when the voltage V2 measured by the voltage sensor 260 during execution of the precharge by the precharge circuit 145 satisfies a first predetermined condition, and estimates the completion of the precharge when the voltage V2 measured by the voltage sensor 260 after the activation attempt satisfies a second predetermined condition.

With this configuration, the FCMGECU 240 can obtain information for estimating the completion of the precharge in the BATT and load system 100 without requiring communication between the BATT and load system 100 and the FC system 200. That is, the activation attempt is instructed at time tc (FIG. 3A) at which a predetermined first condition is satisfied on the basis of the voltage V2 measured by the voltage sensor 260, and the FC system 200 consumes a certain amount of power. Then, the completion of the precharge in the BATT and load system 100 is estimated on the basis of whether or not a predetermined second condition is satisfied on the basis of the voltage V2 measured by the voltage sensor 260 after the activation attempt.

Accurately estimating the completion of the precharge in the BATT and load system 100 eliminates concerns associated with the technology in the related art, and enables reliable activation of the FC system 200 using the battery power after the completion of the precharge.

Furthermore, since communication between the BATT and load system 100 as the first system and the FC system 200 as the second system and an interface for the communication are unnecessary, cost reduction and improved versatility can be achieved.

(2) In the activation apparatus (240, 260), in a case where the voltage V2 measured by the voltage sensor 260 after the activation attempt does not satisfy the second predetermined condition, the FCMGECU 240 instructs the end of the activation attempt, and in a case where the voltage V2 measured by the voltage sensor 260 during the execution of the precharge satisfies the first predetermined condition, the FCMGECU 240 instructs the activation attempt of the FC system 200 again.

With this configuration, it is possible to appropriately handle a case where the precharge has not been completed at time tc (FIG. 3B) at which the activation attempt is instructed. Specifically, it is possible to wait until the predetermined first condition is satisfied again on the basis of the voltage V2 measured by the voltage sensor 260 after the end of the activation attempt at time td (FIG. 3B), and to instruct the activation attempt of the FC system 200 again at time te (FIG. 3B).

(3) In the activation apparatus (240, 260), the FCMGECU 240 sets a state where a first predetermined time has elapsed after the voltage V2 measured by the voltage sensor 260 before the activation attempt reaches a predetermined state, as the first predetermined condition, and increases the first predetermined time as the number of instructions for the activation attempt is increased.

With this configuration, in a case where precharge completion cannot be estimated after an activation attempt is instructed, it is possible to ensure a longer time until the next activation attempt.

(4) In the activation apparatus (240, 260), the FCMGECU 240 includes, in a predetermined state, a condition where a time derivative value of the voltage V2 measured by the voltage sensor 260 before the activation attempt is equal to or less than a first predetermined value.

With this configuration, it is possible to accurately ascertain the behavior of the voltage V2 during the execution of the precharge in the BATT and load system 100 and to appropriately estimate the completion of the precharge in the BATT and load system 100.

(5) In the activation apparatus (240, 260), the FCMGECU 240 sets a state where the voltage V2 measured by the voltage sensor 260 after the activation attempt is equal to or greater than a second predetermined value and a second predetermined time has elapsed from the activation attempt, as the second predetermined condition.

With this configuration, it is possible to accurately ascertain the behavior of the voltage V2 after the activation attempt is instructed and to appropriately estimate the completion of the precharge in the BATT and load system 100.

(6) In the activation apparatus (240, 260), when the completion of the precharge is estimated, the FCMGECU 240 permits the activation of the FC system 200.

With this configuration, it is possible to appropriately activate the second system using the battery power after the completion of the precharge in the BATT and load system 100.

(7) In the activation apparatus (240, 260), the FC system 200 is activated by receiving power supply from the BATT and load system 100, starts power generation by the activation, and supplies the FC power to the BATT and load system 100.

With this configuration, it is possible to appropriately activate the FC system 200 as the second system.

(8) In the activation apparatus (240, 260), the precharge circuit 145 includes the resistor 141 and the precharge contactor 142. The precharge contactor 142 of the precharge circuit 145 is configured to be in a connected (ON) state during the execution of the precharge, and to be in a disconnected (OFF) state after the completion of the precharge.

With this configuration, it is possible to appropriately estimate the completion of the precharge on the basis of the voltage measured by the voltage sensor 260.

The above embodiments can be modified in various manners. Hereinafter, modified examples will be described.

In the embodiment, an example in which the first system is applied to a vehicle has been described, but the first system may also be mounted not only on vehicles such as commercial vehicles or construction machinery but also on aircraft, ships, and the like. In addition, the first system may be applied not only to a mobile body such as the above-mentioned vehicle, but also to stationary power sources installed in residences, factories, public facilities, and the like.

In the embodiment described above, a configuration has been exemplified in which a communication interface is not provided between the first system (for example, the BATT and load system 100) and the second system (for example, the FC system 200) that constitute the overall system 1. However, the present invention is also applicable in a case where the first system and second system are provided with the communication interface so that communication can be performed between the first system and the second system, or in a case where the second system is configured to be provided with information (for example, information indicating the completion of the precharge) of the first system from an external control device or the like. Specifically, even in a case where the communication interface between the first system and the second system fails, or in a case where information of the first system cannot be provided to the second system due to a failure of an external control device or the like, the second system can be appropriately activated using the battery power after the completion of the precharge on the first system side.

In addition, the standby time, duration, elapsed time, and the like exemplified in the embodiment are merely examples and may be changed as appropriate. In addition, the threshold values Tth1 and Tth2 used in the determination processing may also be changed as appropriate.

According to the present invention, when the second system is activated by power from the first system, it becomes possible to appropriately estimate completion of precharge of the first system on the side of the second system.

According to the present invention, in a case where the second system is activated by the power from the first system, it is possible for the second system to appropriately estimate the completion of the precharge on the first system side.

What is claimed is:

1. An activation apparatus for a second system, which activates by receiving power supply from a first system different from the second system, the first system including a battery, a load that receives power supply from the battery, and a precharge circuit provided on a first power line connecting the battery and the load, wherein
the first system and the second system are connected via a second power line such that the second system and the load are in parallel,
the activation apparatus comprising:
a voltage sensor configured to measure a voltage of the precharge circuit of the first system via the first power line and the second power line; and
a microprocessor, wherein
the microprocessor is configured to perform:
instructing an activation attempt of the second system when a voltage measured by the voltage sensor during execution of the precharge by the precharge circuit satisfies a first predetermined condition; and
estimating completion of the precharge when a voltage measured by the voltage sensor after the activation attempt satisfies a second predetermined condition.

2. The activation apparatus according to claim 1, wherein
the microprocessor is configured to perform
the estimating including, in a case where the voltage measured by the voltage sensor after the activation attempt does not satisfy the second predetermined condition, instructing termination of the activation attempt, and in a case where the voltage measured by the voltage sensor during execution of the precharge satisfies the first predetermined condition, instructing the activation attempt of the second system again.

3. The activation apparatus according to claim 2, wherein
the microprocessor is configured to perform:
the estimating including setting a condition in which a first predetermined time has elapsed after the voltage measured by the voltage sensor before the activation attempt reaches a predetermined state, as the first predetermined condition, and increasing the first predetermined time as the number of instructions for the activation attempt increases.

4. The activation apparatus according to claim 3, wherein
the predetermined state includes a condition in which a time derivative value of the voltage measured by the voltage sensor before the activation attempt is equal to or less than a first predetermined value.

5. The activation apparatus according to claim 1, wherein
the microprocessor is configured to perform
the estimating including setting a condition in which the voltage measured by the voltage sensor after the activation attempt is equal to or greater than a second predetermined value and a second predetermined time has elapsed from the activation attempt, as the second predetermined condition.

6. The activation apparatus according to claim 1, wherein
the microprocessor is configured to perform permitting activation of the second system when the completion of the precharge is estimated.

7. The activation apparatus according to claim 1, wherein
the second system is configured to be activated by receiving power supply from the first system, to start power generation by the activation, and to supply power generated by the power generation to the first system.

8. The activation apparatus according to claim 1, wherein
the precharge circuit includes a resistor and a contactor, and
the contactor is configured to be in a connected state during execution of the precharge and in a disconnected state after the completion of the precharge.

9. An activation method for a second system, which activates by receiving power supply from a first system different from the second system, the first system including a battery, a load that receives power supply from the battery, and a precharge circuit provided on a first power line connecting the battery and the load, wherein
the first system and the second system are connected via a second power line such that the second system and the load are in parallel,
the activation method comprising:
a step in which an activation apparatus obtains a detection signal from a voltage sensor configured to measure a voltage of the precharge circuit of the first system via the first power line and the second power line, during execution of the precharge by the precharge circuit;
a step in which the activation apparatus instructs an activation attempt of the second system when the voltage based on the detection signal obtained from the sensor satisfies a first predetermined condition; and
a step in which the activation apparatus estimates completion of the precharge when the voltage based on the detection signal obtained from the sensor after the activation attempt satisfies a second predetermined condition.
